(19) United States
(12) Patent Application Publication
(10) Pub. No.: US 2025/0316637 A1
(43) Pub. Date: Oct. 9, 2025

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: Hui Yeong JANG, Suwon-si (KR); Cheol KIM, Suwon-si (KR)

(21) Appl. No.: 19/098,789

(22) Filed: Apr. 2, 2025

(30) Foreign Application Priority Data
Apr. 5, 2024 (KR) 10-2024-0046490

(51) Int. Cl. H01L 23/00; H01L 23/31; H01L 25/07

(52) U.S. Cl. CPC H01L 24/29; H01L 23/3107; H01L 24/16; H01L 24/27; H01L 24/32; H01L 24/73; H01L 24/14; H01L 25/074; H01L 2224/14134; H01L 2224/14154; H01L 2224/14179; H01L 2224/16145; H01L 2224/16227; H01L 2224/2784; H01L 2224/29011; H01L 2224/29018; H01L 2224/32145; H01L 2224/32225; H01L 2224/73204; H01L 2225/06513; H01L 2225/06517; H01L 2225/06541; H01L 2225/06565

(57) ABSTRACT

A semiconductor package and a method for manufacturing the same are provided. The semiconductor package includes: a substrate extending in first and second directions intersecting each other; a non-conductive material layer on the substrate; and a semiconductor chip on the non-conductive material layer, wherein the non-conductive material layer includes a plurality of first recess areas, wherein each of the plurality of first recess areas extends in the first direction and inwardly of a side surface of the semiconductor chip, wherein the plurality of first recess areas are spaced apart from each other in the second direction, wherein at least one of the plurality of first recess areas defines a void.

### CROSS-REFERENCE TO RELATED APPLICATION

This application claims priority under 35 U.S.C. 119 from Korean Patent Application No. 10-2024-0046490, filed on Apr. 5, 2024 in the Korean Intellectual Property Office, the contents of which are herein incorporated by reference in their entirety.

### FIELD

The present disclosure relates to a semiconductor package and a method for manufacturing the same. More specifically, the present disclosure relates to a semiconductor package including a non-conductive material layer and a method for manufacturing the same.

### BACKGROUND

A semiconductor package may include a plurality of semiconductor chips stacked on a substrate. The substrate and the semiconductor chips may be connected to each other via bumps. The substrate and the semiconductor chips may be bonded to each other via a non-conductive material. Afterwards, a mold layer surrounding the semiconductor chips may be formed to manufacture the semiconductor package.

In this regard, in a process of attaching the semiconductor chips to the substrate, a portion of the non-conductive material may be disposed on a side surface of each of the semiconductor chips and may be exposed. Furthermore, due to a difference between physical properties of the exposed non-conductive material and the mold layer, reliability of the semiconductor package may be reduced.

### SUMMARY

A technical purpose that the present disclosure seeks to achieve is to provide a semiconductor package with improved reliability.

Another technical purpose that the present disclosure seeks to achieve is to provide a method for manufacturing a semiconductor package with improved reliability.

Purposes according to the present disclosure are not limited to the above-mentioned purposes. Other purposes and advantages according to the present disclosure that are not mentioned may be understood based on following descriptions, and may be more clearly understood based on example embodiments according to the present disclosure. Further, it will be easily understood that the purposes and advantages according to the present disclosure may be realized based on the claims and combinations thereof.

A semiconductor package according to some embodiments of the present disclosure includes: a substrate extending in first and second directions intersecting each other; a non-conductive material layer on the substrate; and a semiconductor chip on the non-conductive material layer, wherein the non-conductive material layer includes a plurality of first recess areas, wherein each of the plurality of first recess areas extends in the first direction and inwardly of a side surface of the semiconductor chip, wherein the plurality of first recess areas are spaced apart from each other in the second direction, wherein at least one of the plurality of first recess areas defines a void.

A semiconductor package according to some embodiments of the present disclosure includes: a substrate extending in first and second directions perpendicular to each other; a non-conductive material layer on the substrate; a semiconductor chip on the non-conductive material layer; bump structures between the substrate and the semiconductor chip and electrically connecting the substrate and the semiconductor chip to each other; and a mold layer on the substrate and surrounding a side surface of the semiconductor chip, wherein the non-conductive material layer includes a plurality of first recess areas, wherein each of the plurality of first recess areas extends in the first direction, wherein the plurality of first recess areas are spaced apart from each other in the second direction, wherein each of the plurality of first recess areas is between groups of the bump structures, wherein at least one of the plurality of first recess areas defines an empty space therein.

A method for manufacturing a semiconductor package according to some embodiments of the present disclosure includes: providing a substrate extending in first and second directions intersecting each other; providing a non-conductive film extending in the first and second directions; and removing a portion of the non-conductive film to form a non-conductive material layer including a plurality of recess areas, wherein the plurality of recess areas extend in the first direction and are spaced apart from each other in the second direction, wherein at least one of the plurality of recess areas has a void defined therein.

Specific details of other example embodiments are included in the detailed description and drawings.

### BRIEF DESCRIPTION OF DRAWINGS

The above and other aspects and features of the present disclosure will become more apparent by describing in detail example embodiments thereof with reference to the attached drawings, in which:

FIG. 1 is a plan view for illustrating a configuration before a dicing process is performed in a process for manufacturing a semiconductor package according to some embodiments;

FIG. 2 is an enlarged view for illustrating an area P in FIG. 1 in a process for manufacturing a semiconductor package according to some embodiments;

FIG. 3 is a diagram for illustrating a semiconductor package according to some embodiments after a dicing process has been performed, and is a diagram corresponding to a cross-sectional view cut along a line I-I in FIG. 2;

FIG. 4 is a diagram for illustrating a semiconductor package according to some embodiments after a dicing process has been performed, and is a diagram corresponding to a cross-sectional view cut along a line II-II in FIG. 2;

FIG. 5 is an enlarged view for illustrating an area P in FIG. 1 in a process for manufacturing a semiconductor package according to some embodiments;

FIG. 6 is a diagram for illustrating a semiconductor package according to some embodiments after a dicing process has been performed, and is a diagram corresponding to a cross-sectional view cut along a line III-III in FIG. 5;

FIG. 7 is a diagram for illustrating a semiconductor package according to some embodiments after a dicing process has been performed, and is a diagram corresponding to a cross-sectional view cut along a line IV-IV in FIG. 5;

FIG. 8 is an enlarged view for illustrating an area P in FIG. 1 in a process for manufacturing a semiconductor package according to some embodiments;

FIG. 9 is a diagram for illustrating a semiconductor package according to some embodiments;

FIG. 10 is a diagram for illustrating a semiconductor package according to some embodiments; and

FIGS. 11 to 15 are diagrams of intermediate structures corresponding to intermediate steps of a process for manufacturing a semiconductor package according to some embodiments.

### DETAILED DESCRIPTION

Hereinafter, example embodiments of the present disclosure are described in detail with reference to the attached drawings. The same reference numerals are used for the same components in the drawings, and duplicate descriptions thereof may be omitted in the interest of brevity.

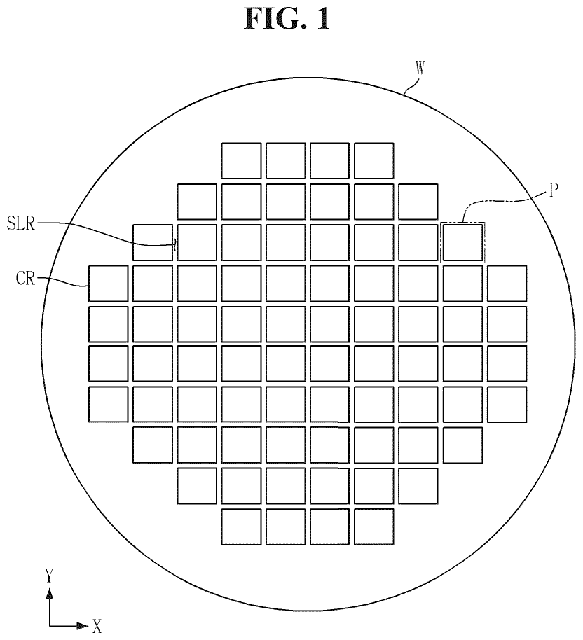

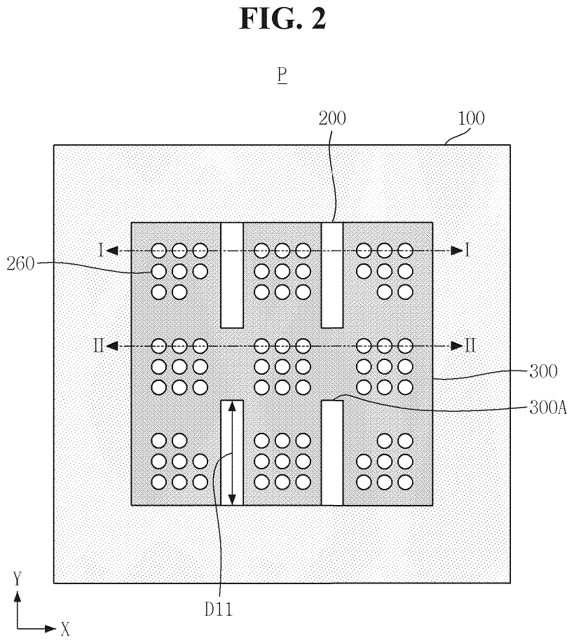

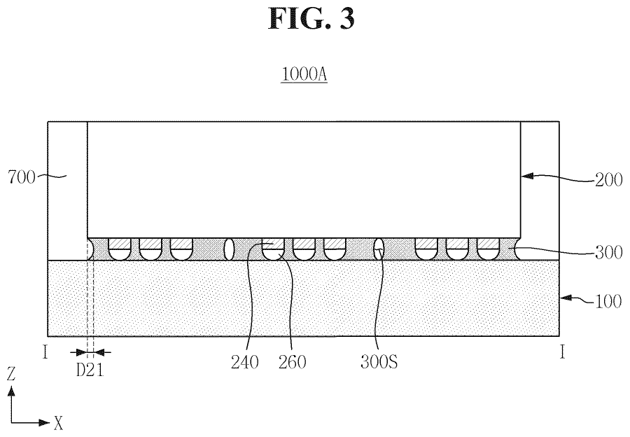

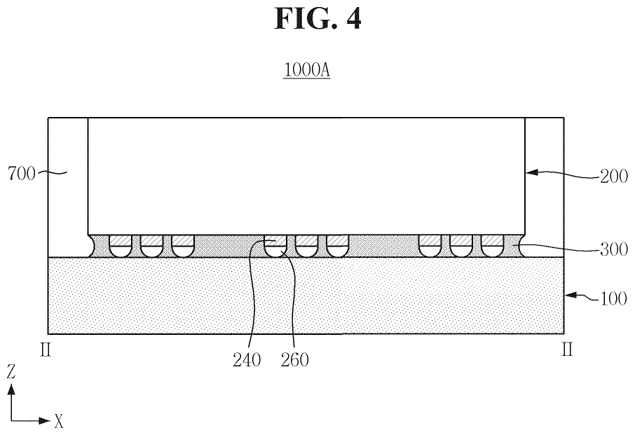

FIG. 1 is a plan view for illustrating a configuration before a dicing process is performed in a process for manufacturing a semiconductor package according to some embodiments. FIG. 2 is an enlarged view for illustrating an area P in FIG. 1 in a process for manufacturing a semiconductor package according to some embodiments. FIG. 3 is a diagram for illustrating a semiconductor package according to some embodiments after a dicing process has been performed, and is a diagram corresponding to a cross-sectional view cut along a line I-I in FIG. 2. FIG. 4 is a diagram for illustrating a semiconductor package according to some embodiments after a dicing process has been performed, and is a diagram corresponding to a cross-sectional view cut along a line II-II in FIG. 2.

Referring to FIG. 1, in a process for manufacturing a semiconductor package according to some embodiments, a wafer W may include at least one chip area or chip region CR and a scribe lane area or scribe lane region SLR surrounding the chip area CR. The chip areas CR may be arranged in a lattice manner while the scribe lane area SLR is positioned between adjacent ones thereof. The wafer W in FIG. 1 may correspond to a substrate 100, which will be described below, and the chip area CR in FIG. 1 may correspond to a semiconductor chip 200, which will be described below.

After the dicing process is performed on the wafer W, the semiconductor package may have substantially the same size as that of the chip area CR. Due to the dicing process, the scribe lane area SLR may be partially and/or entirely lost.

Hereinafter, a semiconductor package according to some embodiments are described in detail.

Referring to FIGS. 2 to 4, a semiconductor package 1000A according to some embodiments may include the substrate 100, the semiconductor chip 200, a non-conductive material layer 300, bump structures 260, and a mold layer 700.

The substrate 100 may include, for example, a printed circuit board (PCB), or a ceramic substrate. However, embodiments of the present disclosure are not limited thereto.

Although not specifically shown, the substrate 100 may include an insulating layer and a wiring layer within the insulating layer.

When the substrate 100 includes the printed circuit board, the insulating layer may be made of at least one material selected from phenol resin, epoxy resin, and polyimide. For example, the insulating layer may include at least one material selected from ABF (Ajinomoto Build-up Film), FR-4, tetrafunctional epoxy, polyphenylene ether, epoxy/polyphenylene oxide, BT (bismaleimide triazine), thermount, cyanate ester, polyimide, and liquid crystal polymer.

One surface of the substrate 100, that is, an upper surface thereof may extend in a first direction Y and a second direction X that intersect each other (or are perpendicular to each other). The semiconductor chips 200 may be stacked on the upper surface of the substrate 100 in a vertical direction (a third direction Z) that intersects each of the first and second directions Y and X (or is parallel to each of the first and second directions Y and X).

Although not specifically shown, a plurality of lower connection terminals may be disposed on the other surface of the substrate 100, that is, a lower surface of the substrate 100. The wiring layer of the substrate 100 may include a conductive material and may electrically connect the semiconductor chip 200 and the lower connection terminals to each other.

The semiconductor chip 200 may be disposed on the substrate 100. The semiconductor chip 200 may be mounted on the substrate 100 in a flip chip bonding manner. A lower surface of the semiconductor chip 200 may face the substrate 100 and may refer to an active surface electrically connected to the substrate 100.

Although not specifically shown, a passivation layer not covering a semiconductor chip pad 240 so as to be exposed may be disposed on the lower surface of the semiconductor chip 200. The exposed semiconductor chip pad 240 not covered with the passivation layer may electrically connect the substrate 100 and the semiconductor chip 200 to each other.

The non-conductive material layer 300 may be disposed on the substrate 100. The semiconductor chip 200 may be disposed on the non-conductive material layer 300. The non-conductive material layer 300 may be disposed under the semiconductor chip 200.

The non-conductive material layer 300 may be interposed between the substrate 100 and the semiconductor chip 200. The non-conductive material layer 300 may be formed to be in or fill a space between the bump structures 260. The non-conductive material layer 300 may protect the substrate 100 and the semiconductor chip 200, and may bond the substrate 100 and the semiconductor chip 200 adjacent to each other to each other.

For example, the non-conductive material layer 300 may be used to bond the substrate 100 and the semiconductor chip 200 to each other in a thermal compression bonding process for bonding the substrate 100 and the semiconductor chip 200 to each other.

The non-conductive material layer 300 may include, for example, NCF (Non-Conductive Film) or NCP (Non-Conductive Paste). However, embodiments of the present disclosure are not limited thereto.

In a plan view, the non-conductive material layer 300 may include a plurality of first recess areas 300A, each extending in the first direction Y and inwardly of the semiconductor chip 200. The plurality of first recess areas 300A may be spaced apart from each other in the second direction X. Each of the plurality of first recess areas 300A may be disposed between the bump structures 260 (or between groups of the bump structures 260).

In the plan view, the plurality of first recess areas 300A may extend in the first direction Y so as to face each other in the first direction Y. Due to the plurality of first recess areas 300A, the non-conductive material layer 300 may have a “ [symbol] ” shape. However, embodiments of the present disclosure are not limited thereto. The plurality of first recess areas 300A may be formed in various shapes depending on an arrangement of the bump structures 260.

More specifically, each of the first recess areas 300A may include sidewalls extending in the first direction Y and facing each other in the second direction X, and inner walls connecting the sidewalls to each other. The sidewalls of each of the first recess areas 300A may extend only within a partial area of the non-conductive material layer 300 in the first direction Y. The inner walls of each of the first recess areas 300A may face each other in the first direction Y.

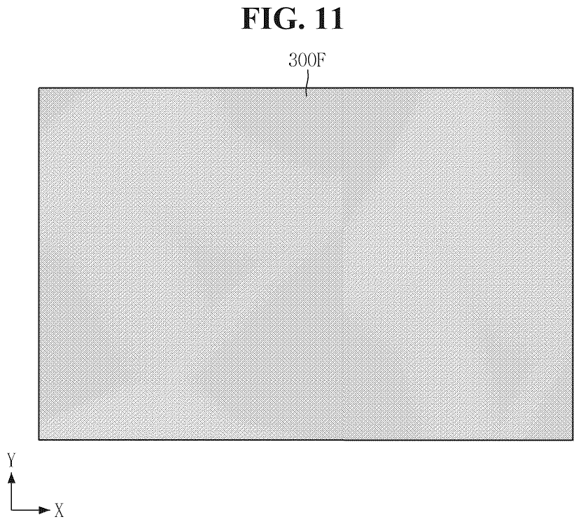

Referring to FIG. 2, each of the plurality of first recess areas 300A may extend by a length or distance D11 in the first direction Y. At least one of the plurality of first recess areas 300A may include or define an empty space 300S, that is, a void 300S. This void may be a structure resulting from removal of a partial area of a non-conductive film (300F in FIG. 11), as will be described later. In FIG. 2, a shape of the void 300S is shown as an elongate oval. However, a specific shape of the void is not limited thereto.

The bump structures 260 may be disposed between the substrate 100 and the semiconductor chip 200 to electrically connect the substrate 100 and the semiconductor chip 200 to each other.

The mold layer 700 may be formed on the substrate 100. The mold layer 700 may surround sidewalls or side surfaces of the semiconductor chip 200 while being disposed on the substrate 100. Accordingly, the mold layer 700 may cover at least a portion of the substrate 100 and the semiconductor chip 200 and protect the substrate 100 and the semiconductor chip 200.

The mold layer 700 may be positioned inwardly of a side surface of the semiconductor chip 200. Referring to FIG. 3, the mold layer 700 may be positioned inwardly the side surface of the semiconductor chip 200 by a length or distance D21.

The mold layer 700 may include, for example, an insulating polymer material such as EMC (epoxy molding compound). The mold layer 700 may include a thermosetting resin such as an epoxy resin, a thermoplastic resin such as polyimide, or a resin such as ABF, FR-4, or BT resin containing a reinforcing material such as a filler.

The filler may include at least one selected from the group consisting of silica (SiO₂), alumina (Al₂O₃), silicon carbide (SiC), barium sulfate (BaSO₄), talc, clay, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and calcium zirconate (CaZrO₃). However, the material of the filler is not limited thereto, and may include a metal material and/or an organic material.

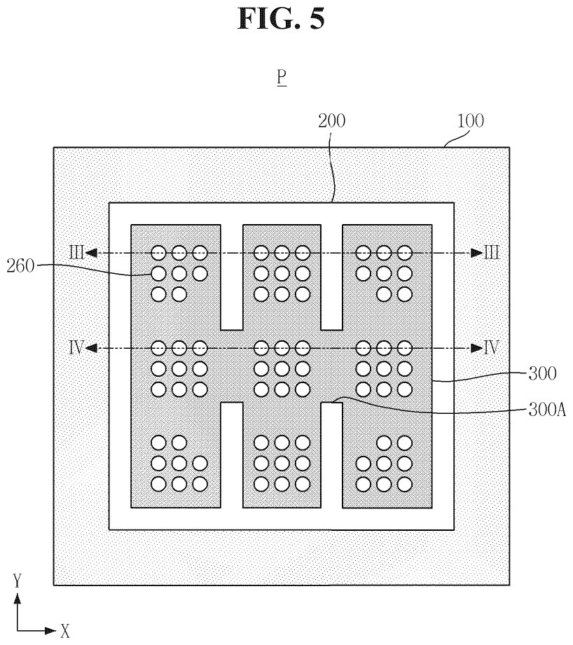

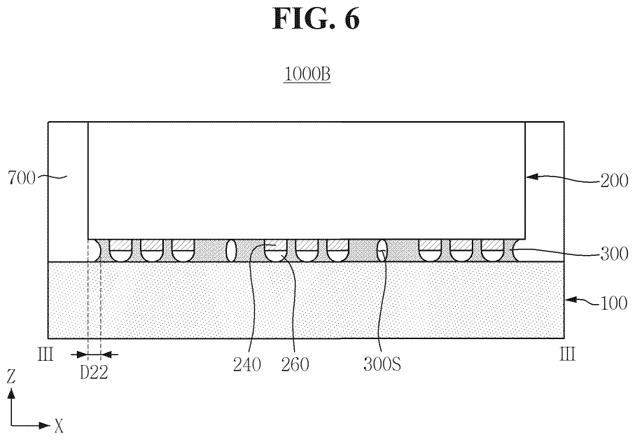

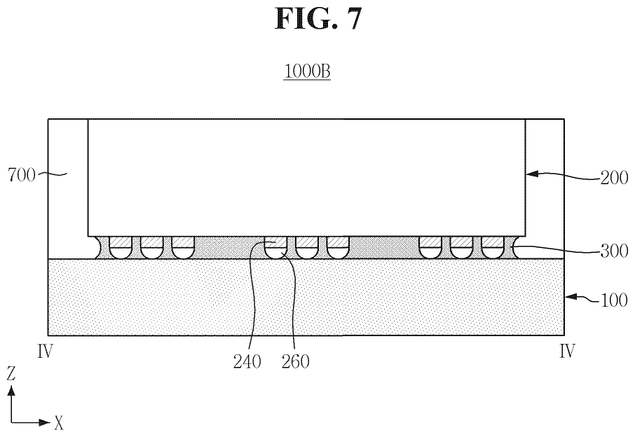

FIG. 5 is an enlarged view for illustrating an area P in FIG. 1 in a process for manufacturing a semiconductor package according to some embodiments. FIG. 6 is a diagram for illustrating a semiconductor package according to some embodiments after a dicing process has been performed, and is a diagram corresponding to a cross-sectional view cut along a line III-III in FIG. 5. FIG. 7 is a diagram for illustrating a semiconductor package according to some embodiments after a dicing process has been performed, and is a diagram corresponding to a cross-sectional view cut along a line IV-IV in FIG. 5. For convenience of description and in the interest of brevity, differences thereof from the descriptions as set forth above with reference to FIG. 1 to FIG. 4 are mainly set forth below.

Referring to FIGS. 5 to 7, the outermost surface of the non-conductive material layer 300 of a semiconductor package 1000B according to some embodiments may be formed inwardly of the semiconductor chip 200.

Accordingly, referring to FIG. 6, the mold layer 700 may be positioned inwardly of the side surface of the semiconductor chip 200 by a length or distance D22. In this regard, based on the second direction X, the length D22 may be larger than the length D21 shown in FIG. 3. In this case, the mold layer 700 may contact a portion of the lower surface of the semiconductor chip 200.

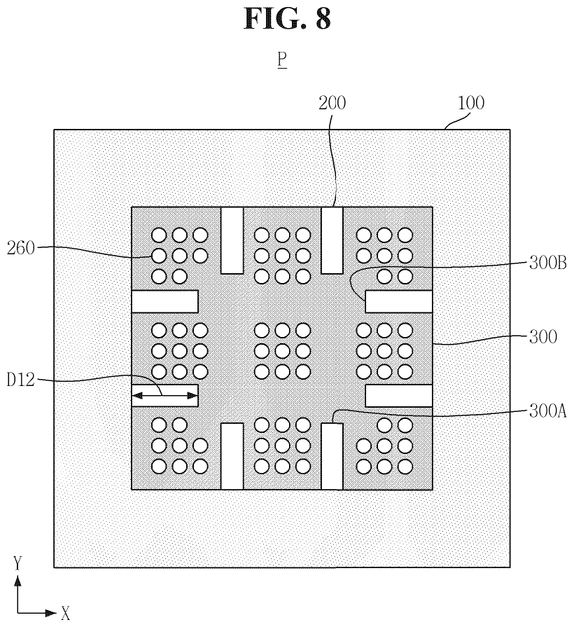

FIG. 8 is an enlarged view for illustrating an area P in FIG. 1 in a process for manufacturing a semiconductor package according to some embodiments. For convenience of description and in the interest of brevity, differences thereof from the descriptions as set forth above with reference to FIG. 1 to FIG. 7 are mainly set forth below.

Referring to FIG. 8, in a plan view, the non-conductive material layer 300 further includes a plurality of second recess areas 300B, each extending in the second direction X and inwardly of the semiconductor chip 200. The second recess areas 300B may be spaced from each other in the first direction Y.

Each of the plurality of second recess areas 300B may extend by a length or distance D12 in the second direction X. At least one of the plurality of second recess areas 300B may include or define an empty space, that is, a void.

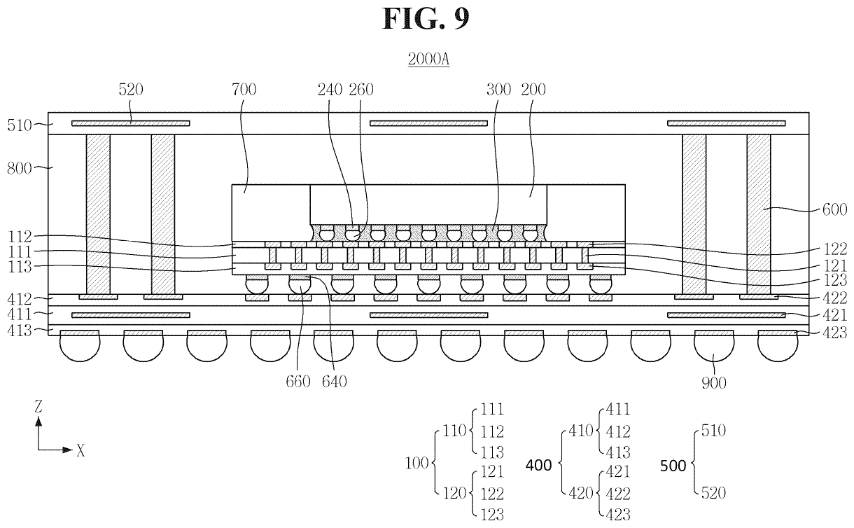

FIG. 9 is a diagram for illustrating a semiconductor package according to some embodiments. For convenience of description and in the interest of brevity, differences thereof from the descriptions as set forth above with reference to FIG. 1 to FIG. 8 are mainly set forth below.

Referring to FIG. 9, a semiconductor package 2000A according to some embodiments may include the first substrate 100, the semiconductor chip 200, the non-conductive material layer 300, a second substrate 400, an interposer 500, a through-via 600, the first mold layer 700, a second mold layer 800, and an external connection terminal 900.

The first substrate 100 may include an insulating layer 110 and a wiring layer 120 disposed within the insulating layer 110. The insulating layer 110 may include an insulating film 111 and first and second solder resist layers 112 and 113 on the insulating film 111. The wiring layer 120 may include first and second connection pads 122 and 123 respectively in the first and second solder resist layers 112 and 113, and a wiring via 121 in the insulating film 111.

One surface, that is, the upper surface, of the first substrate 100 may extend in the first direction Y and the second direction X. The semiconductor chips 200 may be stacked on the upper surface of the substrate 100 in the third direction Z, that is, vertically.

A lower connection pad 640 and a second lower connection terminal 660 may be disposed on the other surface, that is, the lower surface of the first substrate 100. The wiring layer 120 of the first substrate 100 may electrically connect the semiconductor chip 200 and the second lower connection terminal 660 to each other.

The first substrate 100 may include, for example, a printed circuit board (PCB), or a ceramic substrate. However, the present disclosure is not limited thereto.

When the first substrate 100 includes the printed circuit board, the insulating film 111 may be made of at least one material selected from phenol resin, epoxy resin, and polyimide. For example, the insulating film 111 may include at least one material selected from ABF (Ajinomoto Build-up Film), FR-4, tetrafunctional epoxy, polyphenylene ether, epoxy/polyphenylene oxide, BT (bismaleimide triazine), thermount, cyanate ester, polyimide, and liquid crystal polymer.

The first solder resist layer 112 and the second solder resist layer 113 may be disposed on top of and under the insulating film 111, respectively. Each of the first solder resist layer 112 and the second solder resist layer 113 may include, for example, PID (photoimageable dielectric). However, embodiments of the present disclosure are not limited thereto.

At least a portion of the first connection pad 122 may not be covered with or surrounded by the first solder resist layer 112 so as to exposed. The exposed first connection pad 122 may be electrically connected to the semiconductor chip 200.

The second solder resist layer 113 may be disposed on the other surface of the insulating film 111. The second connection pad 123 may not be covered with the second solder resist layer 113 so as to be exposed. The exposed second connection pad 123 may be electrically connected to the second lower connection terminal 660.

The wiring layer 120 may be embodied as a stack of multiple layers. Although not specifically shown, the wiring layer 120 may include a plurality of wiring vias formed therein for electrically connecting the second connection pad 123 and the lower connection pad 640 to each other. The wiring layer 120 may include, for example, a conductive material. For example, the wiring layer 120 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy thereof.

The second lower connection terminal 660 may electrically connect the first substrate 100 and the second substrate 400 to each other. Accordingly, the second lower connection terminal 660 may provide an electrical signal to the first substrate 100, or may provide an electrical signal provided from the first substrate 100 to the second substrate 400.

A shape of the second lower connection terminal 660 may be, for example, spherical or hemispherical or elliptical. However, embodiments of the present disclosure are not limited thereto. The lower connection terminal 660 may include at least one of, for example, tin (Sn), indium (In), lead (Pb), zinc (Zn), nickel (Ni), gold (Au), silver (Ag), copper (Cu), antimony (Sb), bismuth (Bi) and combinations thereof. However, the present disclosure is not limited thereto.

The semiconductor chip 200 may be disposed on the first substrate 100. The above description regarding the semiconductor chip 200, the semiconductor chip pad 240, and the lower connection terminal or bump structure 260 as set forth above in connection with FIGS. 2 to 4 may be similarly applied to descriptions regarding the semiconductor chip 200, the semiconductor chip pad 240, and the first lower connection terminal 260 in FIG. 9.

Although not specifically shown, the non-conductive material layer 300 may include a plurality of recess areas that extend in the first direction Y and inwardly of the semiconductor chip 200 and are spaced apart from each other in the second direction X. Each of the plurality of recess areas may be disposed between the bump structures 260. At least one of the plurality of recess areas may have or define an empty space, that is, a void.

The description regarding the non-conductive material layer 300 as set forth above in connection with FIGS. 1 to 8 may be similarly applied to description regarding the non-conductive material layer 300 in FIG. 9.

The second substrate 400 may include an insulating layer 410 and a wiring layer 420 within the insulating layer 410. The insulating layer 410 may include an insulating film 411, and first and second solder resist layers 412 and 413 on the insulating film 411. The wiring layer 420 may include first and second connection pads 422 and 423 respectively in the first and second solder resist layers 412 and 413, and a wiring pad 421 in the insulating film 411.

One surface, that is, an upper surface, of the second substrate 400 may extend in the first direction Y and the second direction X. The first substrate 100 may be stacked on the upper surface of the second substrate 400 in the third direction Z, that is, the vertical direction.

A plurality of external connection terminals 900 may be disposed on the other surface, that is, a lower surface of the second substrate 400. The wiring layer 420 of the second substrate 400 may electrically connect the first substrate 100 and the external connection terminal 900 to each other.

The second substrate 400 may include, for example, a printed circuit board (PCB) or a ceramic substrate. However, the present disclosure is not limited thereto.

When the second substrate 400 includes a printed circuit board, the insulating film 411 may be made of at least one material selected from phenol resin, epoxy resin, and polyimide. For example, the insulating film 411 may include at least one material selected from ABF (Ajinomoto Build-up Film), FR-4, tetrafunctional epoxy, polyphenylene ether, epoxy/polyphenylene oxide, BT (bismaleimide triazine), thermount, cyanate ester, polyimide, and liquid crystal polymer.

The first solder resist layer 412 and the second solder resist layer 413 may be disposed on top of and under the insulating film 411, respectively. Each of the first solder resist layer 412 and the second solder resist layer 413 includes, for example, PID (photoimageable dielectric). However, embodiments of the present disclosure are not limited thereto.

At least a portion of the first connection pad 422 may not be covered with the first solder resist layer 412 so as to be exposed. The exposed first connection pad 422 may be electrically connected to the first substrate 100.

The second solder resist layer 413 may be disposed on the other surface of the insulating film 411. The second connection pad 423 may not be covered with the second solder resist layer 413 so as to be exposed. The exposed second connection pad 423 may be electrically connected to the external connection terminal 900.

The wiring layer 420 may be embodied as a stack of multiple layers. Although not specifically shown, the wiring layer 420 may further include a plurality of vias formed therein for electrically connecting the first connection pad 422 and the second connection pad 423 to each other.

The wiring layer 420 may include, for example, a conductive material. For example, the wiring layer 420 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy thereof.

The interposer 500 may be disposed on the second substrate 400. The interposer 500 may include an insulating layer 510 and a wiring layer 520. The interposer 500 may be electrically connected to the second substrate 400 through a through-via 600, which will be described below. For example, the interposer 500 may be, but is not limited to, a silicon interposer.

The through-via 600 may be disposed between the second substrate 400 and the interposer 500. The through-via 600 may extend through the second mold layer 800, which will be described below. For example, the through-via 600 may include copper (Cu). However, embodiments of the present disclosure are not limited thereto.

The first mold layer 700 may be formed on the first substrate 100. The first mold layer 700 may be disposed on the first substrate 100 so as to surround a side surface of the semiconductor chip 200. Accordingly, the first mold layer 700 may at least partially cover and may protect the first substrate 100 and the semiconductor chip 200. The first mold layer 700 may be positioned or extend inwardly from the side surface of the semiconductor chip 200.

The description about the mold layer 700 as set forth above in connection with FIGS. 1 to 8 may be similarly applied to a material of the first mold layer 700 in FIG. 9.

The second mold layer 800 may be formed on the second substrate 400. The second mold layer 800 may be disposed on the second substrate 400 so as to at least partially surround the first substrate 100, the semiconductor chip 200, the lower connection pad 640, the second lower connection terminal 660, and the through-via 600. The second mold layer 800 may surround side surfaces of the first substrate 100, the semiconductor chip 200, the lower connection pad 640, the second lower connection terminal 660, and the through-via 600.

The description about the mold layer 700 as set forth above in connection with FIGS. 1 to 8 may be similarly applied to a material of the second mold layer 800.

The external connection terminal 900 may electrically connect the second substrate 400 to an external device. Accordingly, the external connection terminal 900 may provide an electrical signal to the second substrate 400 or provide an electrical signal provided from the second substrate 400 to the external device.

The external connection terminal 900 may have a spherical or hemispherical or elliptical shape. However, embodiments of the present disclosure are not limited thereto. The external connection terminal 900 may include at least one of, for example, tin (Sn), indium (In), lead (Pb), zinc (Zn), nickel (Ni), gold (Au), silver (Ag), copper (Cu), antimony (Sb), bismuth (Bi) and combinations thereof. However, the present disclosure is not limited thereto.

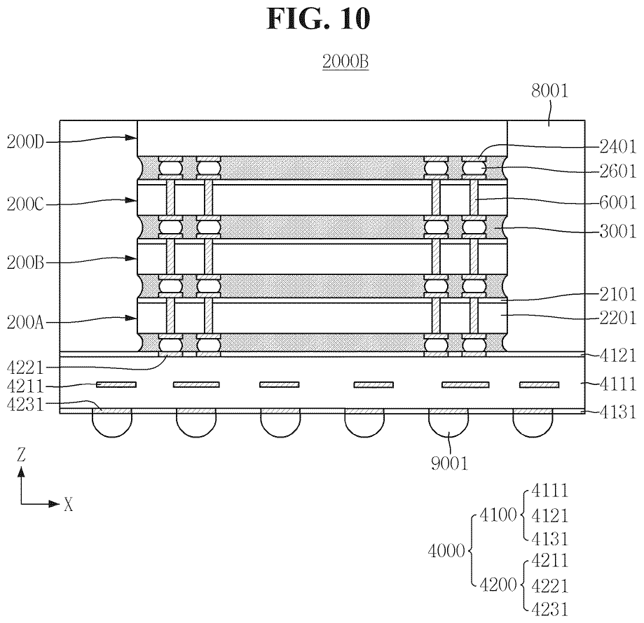

FIG. 10 is a diagram for illustrating a semiconductor package according to some embodiments. For convenience of description and in the interest of brevity, differences thereof from the descriptions as set forth above with reference to FIG. 1 to FIG. 8 are mainly set forth below.

Referring to FIG. 10, a semiconductor package 2000B according to some embodiments may include a third substrate 4000, a plurality of semiconductor chip structures 200A, 200B, 200C, and 200D, non-conductive material layer structures 3001, and a third mold layer 8001.

Referring to FIG. 10, the semiconductor package 2000B of some embodiments may include the four semiconductor chip structures 200A, 200B, 200C, and 200D stacked on the substrate 4000, and through-vias 6001 extending through the first to third semiconductor chip structures 200A, 200B, and 200C. The first to fourth semiconductor chip structures 200A, 200B, 200C, and 200D may be electrically connected to each other via the through-vias 6001 and bump structures 2601.

In FIG. 10, an example in which the first to fourth semiconductor chip structures 200A, 200B, 200C, and 200D are stacked on the third substrate 4000 is shown. However, the number of semiconductor chips stacked on the third substrate 4000 is not limited to four. For example, two, three, or five or more semiconductor chips may be stacked on the third substrate 4000.

The third substrate 4000 may include an insulating layer 4100 and a wiring layer 4200 within the insulating layer 4100. The insulating layer 4100 may include an insulating film 4111 and first and second solder resist layers 4121 and 4131 on the insulating film 4111. The wiring layer 4200 may include first and second connection pads 4221 and 4231 respectively in the first and second solder resist layers 4121 and 4131, and a wiring pad 4211 in the insulating film 4111.

One surface, that is, an upper surface, of the third substrate 4000 may extend in the first direction Y and the second direction X. The plurality of semiconductor chip structures 200A, 200B, 200C, and 200D may be stacked on the upper surface of the third substrate 4000 in the third direction Z, that is, the vertical direction.

A plurality of external connection terminals 9001 may be disposed on the other surface, that is, a lower surface of the third substrate 4000. The wiring layer 4200 of the third substrate 4000 may electrically connect the plurality of semiconductor chip structures 200A, 200B, 200C, 200D to the external connection terminal 9001.

The third substrate 4000 may include, for example, a printed circuit board (PCB) or a ceramic substrate. However, embodiments of the present disclosure are not limited thereto.

When the third substrate 4000 includes the printed circuit board, the insulating film 4111 may be made of at least one material selected from phenol resin, epoxy resin, and polyimide. For example, the insulating film 4111 may include at least one material selected from ABF (Ajinomoto Build-up Film), FR-4, tetrafunctional epoxy, polyphenylene ether, epoxy/polyphenylene oxide, BT (bismaleimide triazine), thermount, cyanate ester, polyimide, and liquid crystal polymer.

The first solder resist layer 4121 and the second solder resist layer 4131 may be disposed on upper and lower surfaces of the insulating film 4111, respectively. Each of the first solder resist layer 4121 and the second solder resist layer 4131 may include, for example, PID (photoimageable dielectric). However, embodiments of the present disclosure are not limited thereto.

At least a portion of the first connection pad 4221 may not be covered with the first solder resist layer 4121 so as to be exposed. The exposed first connection pad 4221 may electrically connect the wiring layer 4200 to the plurality of semiconductor chip structures 200A, 200B, 200C, and 200D.

The second solder resist layer 4131 may be disposed on the other surface of the insulating film 4111. The second connection pad 4231 may not be covered with the second solder resist layer 4131 so as to be exposed. The exposed second connection pad 4231 may be electrically connected to the external connection terminal 9001.

The wiring layer 4200 may be embodied as a stack of multiple layers. Although not specifically shown, the wiring layer 4200 may further include a plurality of vias formed therein for electrically connecting the first connection pad 4221 and the second connection pad 4231 to each other.

The wiring layer 4200 may include, for example, a conductive material. For example, the wiring layer 4200 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy thereof.

The plurality of semiconductor chip structures 200A, 200B, 200C, and 200D may be stacked on the third substrate 4000 and may be electrically connected to each other via the through-vias 6001 and the bump structures 2601.

The through-vias 6001 connected to each of the first to third semiconductor chip structures 200A, 200B, and 200C may extend through the protection layers 2101 and element isolation layers 2201. The through-vias 6001 may be connected to connection pads 2401 disposed on top of and under the through-vias 6001. The through-via 6001 extending through the first semiconductor chip structure 200A may be connected to the connection pad 2401 and thus may be electrically connected to the bump structure 2601. The through-vias 6001 extending through each of the second to third semiconductor chip structures 200B and 200C may be connected to the connection pads 2401 and thus may be electrically connected to the bump structures 2601.

Although not specifically shown, the non-conductive material layer structure 3001 may include a plurality of recess areas that extend in the first direction Y and inwardly of the semiconductor chip 200 and are spaced apart from each other in the second direction X. Each of the plurality of recess areas may be disposed between the bump structures 2601. At least one of the plurality of recess areas may have an empty space, that is, a void.

The descriptions regarding the non-conductive material layer 300 as set forth above using FIGS. 1 to 8 may be similarly applied to description about the non-conductive material layer structure 3001 in FIG. 10.

The third mold layer 8001 may be formed on the third substrate 4000. The third mold layer 8001 may at least partially surround the semiconductor chip structures 200A, 200B, 200C, and 200D while being disposed on the third substrate 4000. Accordingly, the third mold layer 8001 may at least partially cover and may protect the third substrate 4000 and the semiconductor chip structures 200A, 200B, 200C, and 200D. The third mold layer 8001 may be positioned or extend inwardly of a side surface of each of the semiconductor chip structures 200A, 200B, 200C, and 200D.

The description about the mold layer 700 as set forth above using FIGS. 1 to 8 may be similarly applied to a material of the third mold layer 8001.

The external connection terminal 9001 may electrically connect the third substrate 4000 to an external device. Accordingly, the external connection terminal 9001 may provide an electrical signal to the third substrate 4000 or provide an electrical signal provided from the third substrate 4000 to the external device.

The external connection terminal 9001 may have a spherical or hemispherical or elliptical shape. However, embodiments of the present disclosure are not limited thereto. The external connection terminal 9001 may include at least one of, for example, tin (Sn), indium (In), lead (Pb), zinc (Zn), nickel (Ni), gold (Au), silver (Ag), copper (Cu), antimony (Sb), bismuth (Bi) and combinations thereof. However, embodiments of the present disclosure are not limited thereto.

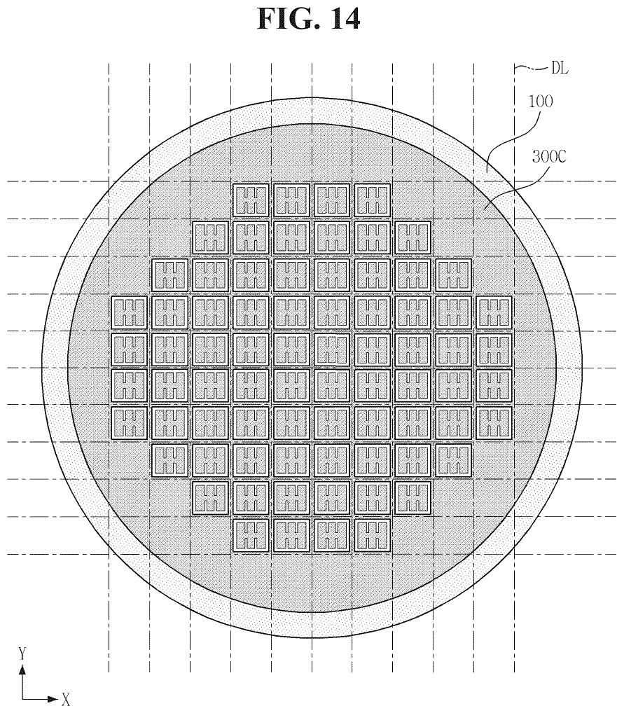

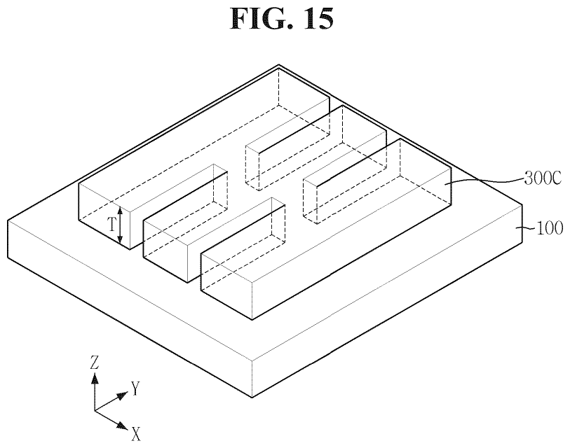

FIGS. 11 to 15 are diagrams of intermediate structures corresponding to intermediate steps of a process for manufacturing a semiconductor package according to some embodiments. By way of example, FIGS. 11 to 15 are diagrams for illustrating a process for manufacturing the semiconductor package as described above in connection with FIGS. 1 to 4. For reference, FIG. 15 is a schematic perspective view of the semiconductor package formed after the dicing process in FIG. 14 has been performed.

Referring to FIG. 11, the non-conductive film 300F extending in each of the first and second directions Y and X may be provided.

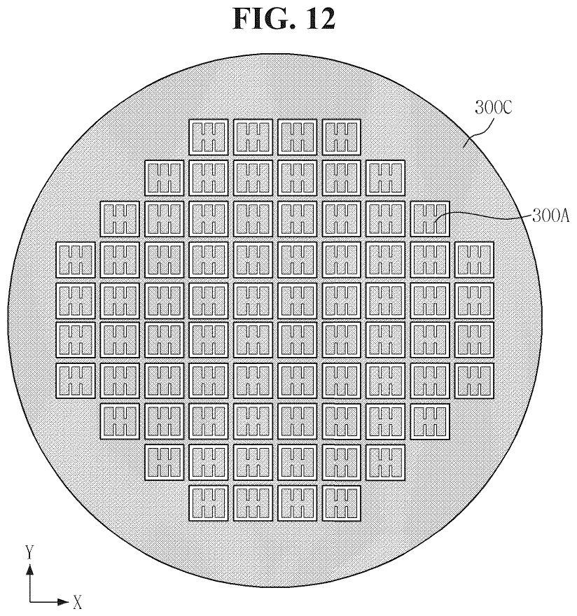

Referring to FIG. 12, a portion of the non-conductive film (300F of FIG. 11) may be removed to form a non-conductive material layer 300C including the plurality of recess areas 300A extending in the first direction Y and spaced apart from each other in the second direction X. At least one of the plurality of recess areas 300A may have or define an empty space, that is, a void therein.

In this case, a portion of the non-conductive film (300F in FIG. 11) may be removed in the third direction Z perpendicular to the first and second directions. A depth by which the non-conductive film (300F in FIG. 11) is removed may be lum or larger. However, embodiments of the present disclosure are not limited thereto.

Although not specifically shown, the non-conductive material layer 300C may be formed by removing the portion of the non-conductive film 300F of FIG. 11 using a device that cuts the non-conductive film (300F of FIG. 11). In this case, the portion of the non-conductive film 300F may be removed by the cutting device of a shape corresponding to a shape of the non-conductive material layer 300C.

In the process of cutting the non-conductive film 300F, the non-conductive material layer 300C may be formed based on the arrangement of the bump structures (260 in FIG. 2). Accordingly, the plurality of recess areas 300A may be formed according to the arrangement of the bump structures (260 in FIG. 2).

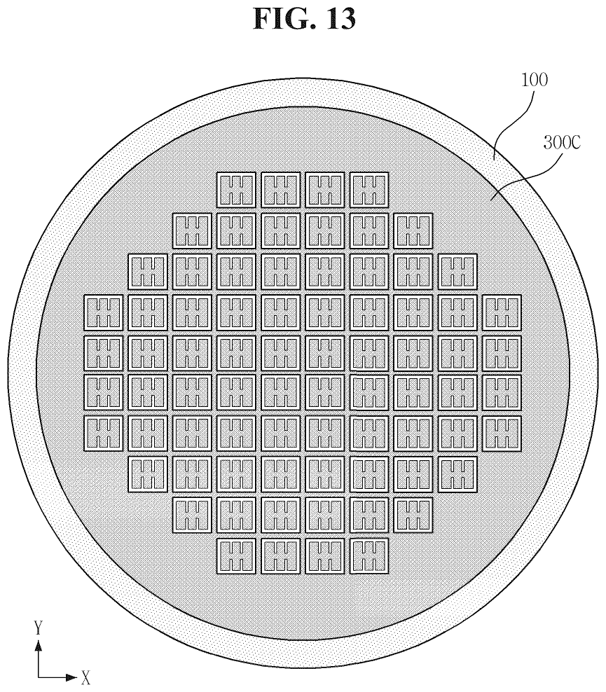

Referring to FIG. 13, the substrate 100 extending in each of the first and second directions Y and X may be provided. The non-conductive material layer 300C may be stacked on the substrate 100.

Referring to FIG. 14, after the non-conductive material layer 300C is formed on the substrate 100, the substrate 100 may be divided into the plurality of chip areas (CR in FIG. 1) in a dicing process. The dicing process may be performed along a dicing line DL, so that the plurality of chip areas (CR in FIG. 1) may be formed.

In this process, referring to FIG. 15, the non-conductive material layer 300C may be formed so as to be positioned inwardly of the chip area (CR in FIG. 1). As the portion of non-conductive film (300F in FIG. 11) is removed, the non-conductive material layer 300C with a predetermined thickness T may be formed.

According to some embodiments, the non-conductive material layer 300 may be formed on the chip area (CR in FIG. 1) and/or the wafer (W in FIG. 1) by removing the portion of the non-conductive film (300F of FIG. 11). Using the non-conductive film (300F of FIG. 11) from which the partial area has been removed, a volume and/or an amount of the non-conductive material layer 300 may be adjusted according to an arrangement design of the bump structures 260, and exposure of the non-conductive material layer 300 to an outside out of the chip area may be minimized.

Although example embodiments of the present disclosure have been described with reference to the accompanying drawings, the present disclosure is not limited to the above embodiments, but may be implemented in various different forms. A person skilled in the art will appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor package comprising:
a substrate extending in first and second directions intersecting each other;
a non-conductive material layer on the substrate; and
a semiconductor chip on the non-conductive material layer,
wherein the non-conductive material layer includes a plurality of first recess areas, wherein each of the plurality of first recess areas extends in the first direction and inwardly of a side surface of the semiconductor chip, wherein the plurality of first recess areas are spaced apart from each other in the second direction, and
wherein at least one of the plurality of first recess areas defines a void.

2. The semiconductor package of claim 1, wherein adjacent ones of the plurality of first recess areas face each other in the first direction.

3. The semiconductor package of claim 1, the non-conductive material layer is positioned inwardly of a side surface of the semiconductor chip.

4. The semiconductor package of claim 1, further comprising bump structures between the substrate and the semiconductor chip and electrically connecting the substrate and the semiconductor chip to each other.

5. The semiconductor package of claim 4, wherein each of the plurality of first recess areas is disposed between groups of the bump structures.

6. The semiconductor package of claim 1, wherein the non-conductive material layer further includes a plurality of second recess areas, wherein each of the plurality of second recess areas extends in the second direction and inwardly of a side surface of the semiconductor chip, wherein the plurality of second recess areas are spaced apart from each other in the first direction.

7. The semiconductor package of claim 6, wherein at least one of the plurality of second recess areas defines a void.

8. The semiconductor package of claim 1, further comprising a mold layer on the substrate and surrounding a side surface of the semiconductor chip,
wherein the mold layer extends inwardly of the side surface of the semiconductor chip.

9. The semiconductor package of claim 1, further comprising:
a plurality of semiconductor chip structures stacked on the semiconductor chip and electrically connected to each other via through-vias and bump structures;
a non-conductive material layer structure between adjacent ones of the plurality of semiconductor chip structures; and
a mold layer on the substrate and surrounding a side surface of the semiconductor chip and side surfaces of the plurality of semiconductor chip structures,
wherein the mold layer extends inwardly of the side surface of the semiconductor chip and the side surfaces of the plurality of semiconductor chip structures.

10. A semiconductor package comprising:
a substrate extending in first and second directions perpendicular to each other;
a non-conductive material layer on the substrate;
a semiconductor chip on the non-conductive material layer;
bump structures between the substrate and the semiconductor chip and electrically connecting the substrate and the semiconductor chip to each other; and
a mold layer on the substrate and surrounding a side surface of the semiconductor chip,
wherein the non-conductive material layer includes a plurality of first recess areas,
wherein each of the plurality of first recess areas extends in the first direction, wherein the plurality of first recess areas are spaced apart from each other in the second direction,
wherein each of the plurality of first recess areas is between groups of the bump structures, and
wherein at least one of the plurality of first recess areas defines an empty space therein.

11. The semiconductor package of claim 10, wherein each of the plurality of first recess areas extends inwardly of a side surface of the semiconductor chip.

12. The semiconductor package of claim 10, wherein the non-conductive material layer further includes a plurality of second recess areas, wherein each of the plurality of second recess areas extends in the second direction, wherein the plurality of second recess areas are spaced apart from each other in the first direction,
wherein each of the plurality of second recess areas is between groups of the bump structures, and
wherein at least one of the plurality of second recess areas defines an empty space therein.

13. The semiconductor package of claim 10, wherein the non-conductive material layer is positioned inwardly of a side surface of the semiconductor chip.

14. The semiconductor package of claim 10, wherein the mold layer extends inwardly of a side surface of the semiconductor chip.

15. The semiconductor package of claim 10, wherein the mold layer is in contact with a portion of a lower surface of the semiconductor chip.

16. A method for manufacturing a semiconductor package, the method comprising:
providing a substrate extending in first and second directions intersecting each other;
providing a non-conductive film extending in the first and second directions; and
removing a portion of the non-conductive film to form a non-conductive material layer including a plurality of recess areas, wherein the plurality of recess areas extend in the first direction and are spaced apart from each other in the second direction,
wherein at least one of the plurality of recess areas has a void defined therein.

17. The method of claim 16, wherein the forming of the non-conductive material layer includes removing the portion of the non-conductive film in a third direction perpendicular to the first and second directions.

18. The method of claim 17, wherein a depth by which the non-conductive film is removed is 1 μm or larger.

19. The method of claim 16, further comprising:
stacking the non-conductive material layer on the substrate; and
dividing the substrate into a plurality of chip areas using a dicing process.

20. The method of claim 19, wherein the non-conductive material layer is positioned inwardly of at least one of the plurality of chip areas.
